(19) United States
(12) Patent Application Publication
(10) Pub. No.: US 2005/0225945 A1
(43) Pub. Date: Oct. 13, 2005

(54) Universal mountable heat sink with integral spring clip

(76) Inventor: Kechuan Liu, Weston, FL (US)

Correspondence Address: Mr. Kevin Liu, 197 Alhambra Way, Weston, FL, 33326, US

(21) Appl. No.: 11/099,378

(22) Filed: Apr. 5, 2005

Related U.S. Application Data
(60) Provisional application No. 60/560,764, filed on Apr. 8, 2004.

(51) Int. Cl. H05K 7/20

(52) U.S. Cl. 361/709; 165/80.3

(57) ABSTRACT

A heat sink apparatus for use with electronic components comprises a base member and an integral spring clip. The base member and the integral spring clip(s) are of unitary construction. The base member is configured to have at least one receiving aperture and one heat-conducting surface with fins extended from or attached to its opposite surface. The integral spring clip comprises solderable elements, i.e. leads and surfaces, and auto-align mechanism feature. The integral spring clip is configured to have fully constrained with the base member, and to flex about an axis resiliently to effect an engaged relation to substantially fixedly maintain the electronic component in abutting relation with heat-conducting surface. The heat sink apparatus can be mounted onto a print circuit or wiring board via either through-hole or surface mounting technology to meet the circuit design and space requirements.

This patent application is associated to the Provisional Patent Application filed on Apr. 8, 2004, Application No. 60/560,764.

### CROSS-REFERENCE TO RELATED APPLICATIONS

None

### STATEMENT REGARDING FEDERAL SPONSORED RESEARCH OR DEVELOPMENT

Not Applicable

### FIELD OF THE INVENTION

This invention generally relates to the art of heat sink assemblies and, particularly, to a universal mountable heat sink assemblies having an embedded integral spring clip comprising solderable elements and auto-align mechanism for both attaching electronic components thereto heat sink body and being soldered onto printed circuit or wiring board.

### BACKGROUND OF THE INVENTION

Heat sinks or heat sink assemblies of a wide variety of designs have been employed to dissipate heat generated by electronic components and devices on printed wiring or circuit boards to prevent the electronic components and devices from failure. More than ever before, today's electronic products are reducing the size and cost, increasing power and speed dramatically, and upgrading frequently. So that the heat sinks or heat sink assemblies used in electronic packaging must be smaller size, larger surface areas, easier assembly, lower cost and flexible mountable to meet the trends.

Generally a heat sink is a piece of part made of any thermal conductive materials, such as Copper, Aluminum and Steel, etc. For better performance and more cost effective, a heat sink usually has extended surface areas, called fins, and is made of Aluminum. A heat sink assembly comprise of at least one heat sink and some attachments, such as clip or clamp, pins or tabs, and/or fasteners, to attach electronic components or devices onto heat sink body, and finally to mount the heat sink assembly into a printed wiring or circuit board.

On a typical printed wiring or circuit board, there may be a number of heat generating electronic components or devices. Conventionally a couple of heat sink assemblies may be used and mounted in different orientations using either though-hole or surface mounting technologies depending upon the circuit design and layout requirements to dissipate the heat. If the electronic product is required for more power or higher speed, or shrink the size, say from 2 U to 1 U height, the heat sink on the printed wiring or circuit board may need to be changed in order to dissipate more heat generated by the devices. Thereby the circuit may need to be redesigned and re-laid out.

In order to improve size, surface areas, flexibility of mounting and cost, more and more heat sink apparatus are constructed unitarily and mounted universally. An example of the latter may be seen in U.S. Pat. No. 6,053,240, the Surface Mount Heat Sink from AAVID Thermalloy. This stamped heat sinks with a pair of solderable and thermally conductive legs is a good example for improving ease of assembly and surface mountable, but is limited in surface areas, performance and mounting options. The electronic component or device is not directly in contact with the heat sink, and the heat sink can only be surface mounted and the through-hole mounting is not an option. In other words, this heat sink is not universal mountable.

Accordingly, what is needed is in the art of a smaller size, larger surface areas, lower cost, universally mountable, and unitarily constructed heat sink apparatus which incorporates the clipping and mounting mechanism, and be ready for attaching electronic components or devices thereon, and universally mounted onto printed wring or circuit board without requiring extra parts.

### SUMMARY OF THE INVENTION

A heat sink apparatus for use with electronic components or devices comprises a base member and an integral spring clip. The base member is configured to have at least one receiving aperture and at least one heat-conducting surface. The base member further has fins attached to its outside surfaces. The base member and the integral spring clip are of unitary and compact construction. The integral spring clip comprises solderable elements and auto-aligning feature for aligning the electronic component when engaging clipping. The integral spring clip is configured to flex about its axis resiliently to effect an engaged relation with the heat conducting surface to substantially fixedly maintain the electronic components in abutting relation with the heat dissipating surface. The heat sink assembly can be mounted onto printed circuit or wiring boards using either through-hole mounting technology or surface mounting technology without the needs of changing fabricating and assembling procedures.

The unitary construction for a heat sink apparatus according to the present invention avoids the necessity for additional assembly parts such as screws, nuts, bolts, washers and adhesives. The heat sink apparatus of the present invention also avoids the requirement for such separate attachments as spring clips and fixtures suitable for clipping mechanism and stabilizing heat sink assembly before being fixed on a printed wiring or circuit board. In such all-in-one solution heat sink apparatus, it greatly reduces the assembly, documentation and inventory costs.

The universal mountable construction for a heat sink apparatus according to the present invention provides the maximum flexibility for circuit design and printed circuit or wiring board layouts. The heat sink apparatus of the present invention also provides the flexibility to accommodate the technologies changes in IC packaging and soldering.

It is a further object of the present invention to provide a heat sink apparatus that the assembly of integral spring clip and the base member together to create unitary construction uses the very cost effective operations without requiring expensive tooling, skilled workers and complicated fixtures. It is, therefore, an object of the present invention to provide a heat sink apparatus that is of unitary construction using cost-effective secondary assembly operation.

It is yet a further object of the present invention to provide a heat sink apparatus that may be assembled with an associated electronic component without unnecessary assembly steps, such as ancillary process operations like drilling or tapping apertures.

It is yet a further object of the present invention to provide a heat sink apparatus that can be mounted (or soldered) onto a printed circuit or wiring board using either through-hole technology or SMT (surface mounting technology) without the needs to change heat sink fabricating and assembling procedures.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

FIGS. 1 is the perspective drawing of an embodiment of the present invention before assembly with electronic components.

FIG. 2 is a perspective drawing of an embodiment of an integral spring clip.

FIGS. 3A and 3B are the projective and partially exploded drawings of views illustrating how the base member and integral spring clip assembled together.

FIGS. 4A, 4B and 4C are the perspective drawings illustrating how to attach electronic components onto the heat sink apparatus of the present invention

FIGS. 5A and 5B are the perspective drawings illustrating how the heat sink assembly apparatus of the present invention can be soldered onto a printed circuit or wiring board using either though-hole mounting or surface mounting technology.

### DETAILED DESCRIPTIONS OF THE INVENTION

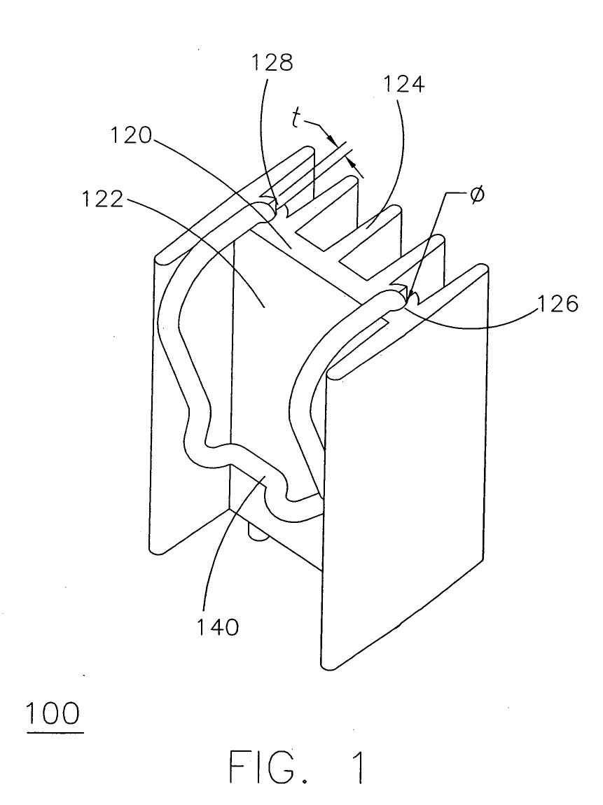

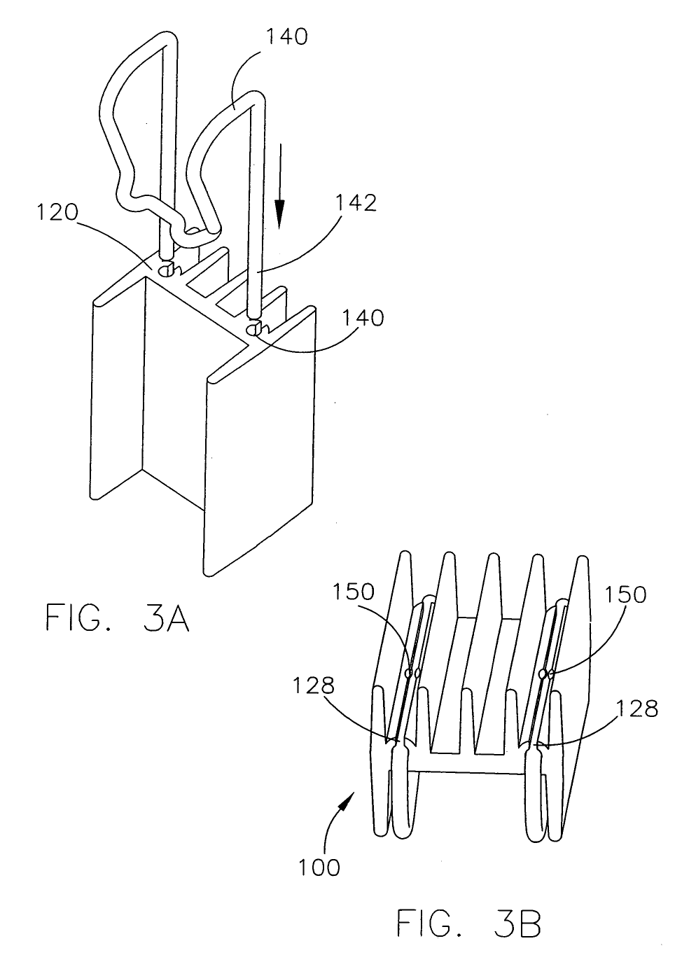

FIG. 1 is the perspective views of a heat sink apparatus constructed according to a preferred embodiment of the present invention. In FIG. 1, a heat sink apparatus 100 comprises a heat sink base member 120 and an integral spring clip 140. Heat sink base member 120 is configured to have at least one heat interface surface 122 and a plurality of extended surface areas or fins 124 attached or born to the opposite and/or same side of heat interface surface 122 for better heat dissipating, and two identical holes 126 with the diameter “φ” which has an opening 128 with a width “t”. The width “t” of the opening 128 should be smaller than the diameter “φ” of hole 126. Heat sink base member 120 is preferably constructed of an inexpensive and better thermal conductive material, such as aluminum, and fabricated by extrusion, casting, machining and the like, preferably extrusion. The fins 124 may be fabricated by extrusion, bonding, brazing, casting, machining or any other manufacturing methods with an inexpensive, better thermal conductive material, such as aluminum. The integral spring clip 140 is configured to be confined within the holes 126 of heat sink base member 120 to have to unitary construction, such constrain, according to present invention, may be effected by sliding the clip 140 into hole 126 then deforming the edges of opening 128 to prevent spring clip 140 to slide out to effect the unitary connection between them, as illustrated in FIGS. 3A and 3B. The sprint clip 140 is preferably constructed of springy and resilient material, such as spring steel, sheet or wire with solderable plating or coating, such as tin or tin-lead plating, and fabricated by forming, stamping or any other inexpensive ways.

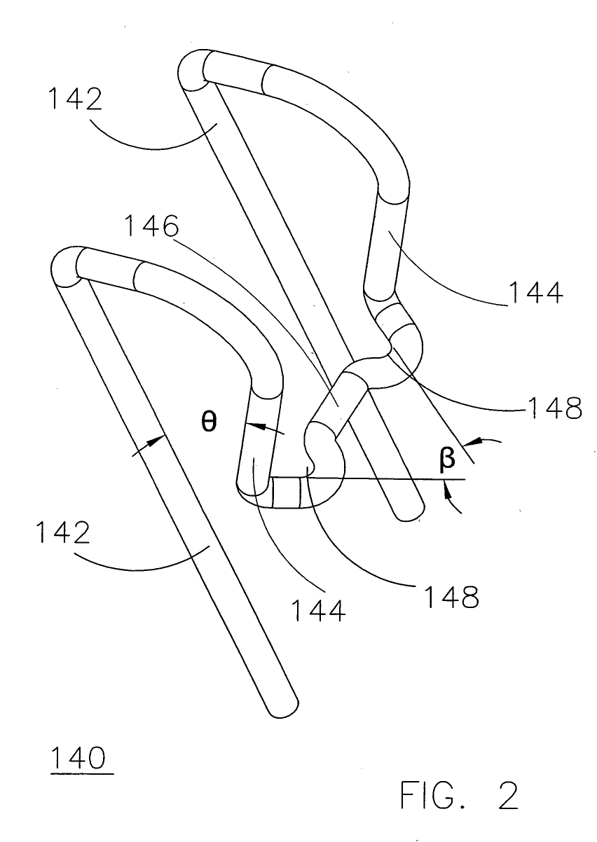

FIG. 2 is a perspective view of the integral spring clip 140 constructed according to a preferred embodiment of the present invention. The spring clip 140 may be manufactured from flat or round wire spring materials, preferably round wire spring material for ease of manufacturing and assembly, and is configured to be “η” shape-like, having a pair of legs 142, and a pair of curved cantilever arms 144 bridged by a clamping beam 146. For effective clipping action and sufficient clipping forces, the curved cantilever arms 144 have to be formed with an angle “θ” with leg 142. Those skilled in the art will know the relationship between the clipping force and the angle “θ”. The curved cantilever arms 144 are also served as solder members for being soldered onto a printed circuit or wiring board known as surface mounting (SMT). The pair of legs 142 is used for attaching the spring clip 140 into heat sink 120 and also served as soldering leads for being soldered into a printed circuit or wiring broad known as through-hole mounting. The length if the legs 142 is depending on the height of heat sink 120 and the soldering methods, i.e. though-hole or surface mounting. Clamping beam 146 is configured to have the auto-center mechanism with a pair of conical shape formed tooling receptacle 148. The angle β for the conical should be greater than 0° and smaller than 90° (0°<β<90°), preferably between 30° and 60°.

FIGS. 3A and 3B are a perspective, partially exploded views of the heat sink apparatus according the present invention, showing how to assemble spring clip 140 onto a heat sink base 120 to effect the unitary connection between them. FIG. 3A shows the spring clip 140 is sliding into its mating apertures, cylinders 126 on heat sink base 120. FIG. 3B shows the spring clip 140 is at the positions with heat sink base 120 after sliding in, and the swaging actions are taken to press the material of the edges of the opening 128 against the legs 142 of clip 140 to create a deformed button 150 which stops spring clip 140 sliding out. At least one deformed button 150 needs to be created for each leg 142 so as to effect the unitary connection between spring clip 140 and heat sink base 120, in other words, after this operation, spring clip 140 and heat sink base 120 can no longer taken apart from heat sink base 120 without destroying the heat sink assembly 100.

### Operations

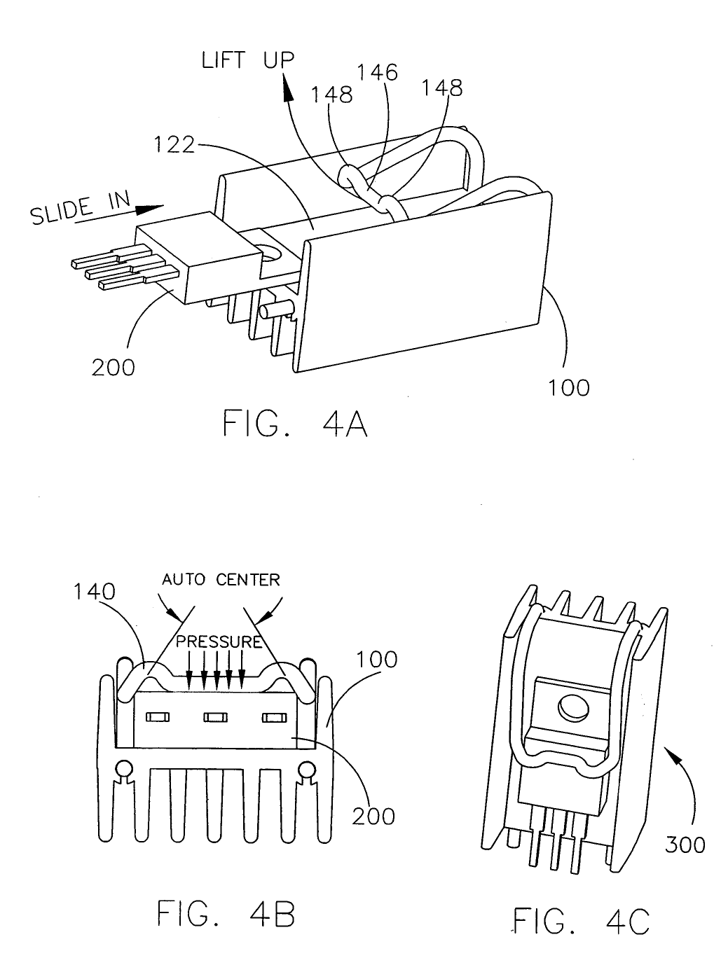

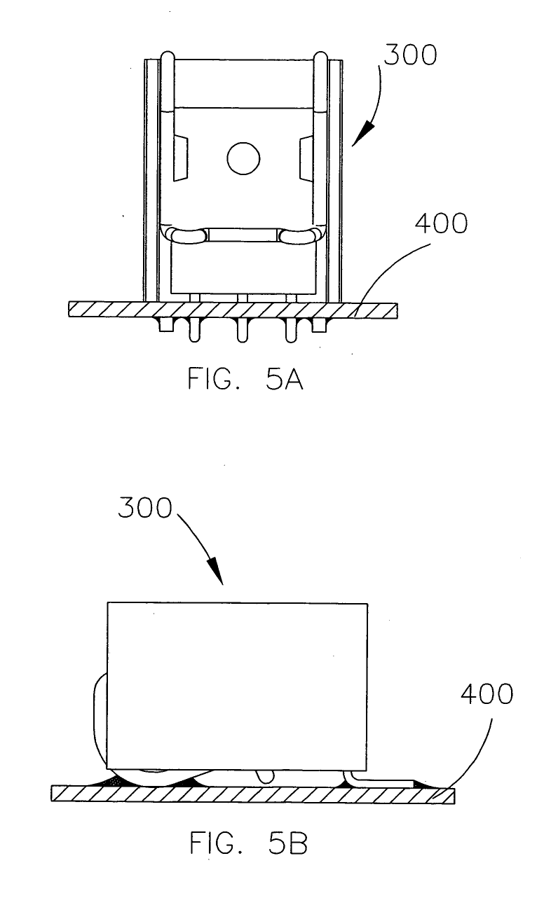

In an operation of using this invention, one uses the heat sink apparatus 100 in a normal manner, clipping the electronic components or devices 200 onto the heat sink apparatus 101 and readily places the whole assembly 300 onto a printed circuit or wiring board for soldering operation like any other electronic components. To clip electronic components or devices onto the heat sink apparatus 100, one should:
1). Slightly lift the clipping beam 146 upside with proper tool in the tooling receptacle 148, as shown in FIG. 4A, so that the clearance between the clipping beam 146 and the heat dissipating surface 122 is bigger than the thickness of the electronic component 200.
2). Slide an electronic components or devices 200 into the gaps as shown in FIG. 4A and release the moment arms 144 so that the clipping beam 146 will push the electronic components or devices 200 against the heat dissipation surface 122 of heat sink base 120 with certain pressure to effect the heat transferring from heat generating electronic components or devices 200 to heat sink 100. Meanwhile the conical-shaped with angle β tooling receptacle will center the electronic components or devices 200 in its position as shown in FIG. 4B. There may be an electrical insulating pad (not shown here) between components or devices 200 and heat dissipation surface 122. The whole heat sink assembly 300 is created and comprises a heat sink apparatus 100 and at least one electronic component or device 200 as shown in FIG. 4C.
3). After finishing assembling the electronic components or devices onto heat sink, the heat sink assembly 300 is ready for being assembled onto printed circuit or wiring boards 400. One can plug the heat sink assembly 300 vertically into a printed circuit or wiring board for soldering operation, which has been well known as through-hole mounting, as shown in FIG. 5A, or one can put the heat sink assembly 300 horizontally onto the surface of a printed circuit or wiring board for soldering operation, which has been well known as surface mounting, as shown in FIG. 5B, depending upon the circuit design and electronic cooling needs. Apparently, this universal mountable heat sink apparatus gives the maximum flexibilities for printed circuit or wiring broad layouts, circuit designs, cooling technologies selecting and managing spacing constraints.

Obviously the present invention provides the heat sink apparatus with advantages as listed below:
1). Universal mountable, through-hole or surface mounting.
2). Ease of assembly & manufacturing
3). Cost effective
4). Small space occupation

Although only a few embodiments of the present invention have been described, it should be understood that the present invention be embodied in many other specific forms without departing from the spirit or the scope of the present invention. The present examples are to be considered as illustrative and not restrictive, and the invention is not to be limited to the details given herein, but may be modified within the scope of the appended claims along with their full scope of equivalents.

1. A heat sink apparatus for use with at least one electronic component; the apparatus comprising:
(a) a base member; and
(b) an integral spring clip;
said base member and said integral spring clip being of unitary construction; said integral spring clip is fully constrained with said base member and configured to flex about at one axis resiliently to effect an engaged relation with said base member; said base member and said integral spring clip cooperating in said engaged relation to substantially fixedly maintain said at least one electronic component in abutting relation with said base member;

2. A heat sink apparatus for use with at least one electronic component as recited in claim 1 wherein said base member comprising at least one heat conducting surface, at least one receiving aperture and a plurality of extended surface areas or fins;

3. A heat sink apparatus for use with at least one electronic component as recited in claim 2 wherein said heat conducting surface having at least a certain smooth area for electronic component to contact with thereon;

4. A heat sink apparatus for use with at least one electronic component as recited in claim 3 wherein said heat conducting surface usually having fins attached or born thereto its opposite side;

5. A heat sink apparatus for use with at least one electronic component as recited in claim 2 wherein said receiving aperture is a hole with an opening;

6. A heat sink apparatus for use with at least one electronic component as recited in claim 5 wherein said hole having a diameter of “φ”;

7. A heat sink apparatus for use with at least one electronic component as recited in claim 5 wherein said opening on said hole having a with of “t” which is smaller than said diameter “φ”;

8. A heat sink apparatus for use with at least one electronic component as recited in claim 1 wherein said integral spring clip configured to be “η” shape-like comprising a pair of legs, and a pair of curved cantilever arms bridged by a clamping beam.

9. A heat sink apparatus for use with at least one electronic component as recited in claim 8 wherein said pair of legs formed with spring wire with diameter slightly smaller than “φ”, and having solderable coating.

10. A heat sink apparatus for use with at least one electronic component as recited in claim 8 wherein said curved cantilever arms having to be formed with an angle “θ” with said leg and having solderable coating

11. A heat sink apparatus for use with at least one electronic component as recited in claim 8 wherein said clamping beam configured to have the auto-center mechanism with a pair of conical shape formed tooling receptacle. The angle β for said conical should be greater than 0° and smaller than 90° (0°<β<90°), preferably between 30° and 60°.

12. A heat sink apparatus for use with at least one electronic component as recited in claim 1 wherein said integral spring clip configured to cooperatively engage a corresponding said receiving aperture (hole) in said base member so that said curved cantilever arms of said integral spring clip is able to swing about one axis; therefore said clamping beam of said curved cantilever arm to substantially fixedly maintain said at least one electronic component in abutting relation with said heat conducting surface area;

13. A heat sink apparatus for use with at least one electronic component; the apparatus comprising:
(a) a base member; and
(b) an integral spring clip;
said base member and filly constraining said spring clip inside said base member; said base member and said spring clip being of unitary construction; said spring clip fully constrained inside of said base member and configured to flex about at least one axis resiliently to effect an engaged relation with said base member; said base member and said spring clip cooperating in said engaged relation to substantially fixedly maintain said at least one electronic component in abutting relation with said base member; said means for said unitary construction of said base member and said spring clip being very economical;

14. A heat sink apparatus for use with at least one electronic component as recited in claim 13 wherein said economic means including machineless and fixtureless assembly operations;

15. A heat sink apparatus for use with at least one electronic component as recited in claim 13 wherein said assembly operations including deforming, half-sheared and swaging;

16. A heat sink apparatus for use with at least one electronic component; the apparatus comprising:
(a) a base member;
(b) an integral spring clip;
(c) means for joining said integral spring clip and said spring clips inside said base frame; and
(e) means of being universally mountable;
said base member and said integral spring clip being of unitary construction; said integral spring clip fully constrained inside of said base member and configured to flex about at least one axis resiliently to effect an engaged relation with said base frame; said base frame and said spring clip cooperating in said engaged relation to substantially fixedly maintain said at least one electronic component in abutting relation with said base frame; said means for said unitary construction of said base member and said integral spring clip being very economical;

17. A heat sink apparatus for use with at least one electronic component as recited in claim 16 wherein said means of being universally mountable are either though-hole mounting or surface mounting.

18. A heat sink apparatus for use with at least one electronic component as recited in claim 17 wherein said means of being universally mountable being made possible by the cooperation of said integral spring clip and said base frame.
